(19) United States
(12) Patent Application Publication
(10) Pub. No.: US 2013/0139380 A1
(43) Pub. Date: Jun. 6, 2013

(54) CHIP BONDING APPARATUS AND CHIP BONDING METHOD USING THE SAME

(71) Applicant: Samsung Electronics Co., Ltd., Suwon-Si (KR)

(72) Inventors: Byung Joon LEE, Yongin-si (KR); Kyoungran KIM, Suwon-si (KR); Sang Yun KIM, Suwon-si (KR); Young Bum KIM, Yongin-si (KR); Seung Dae SEOK, Yingin-si (KR); Jae-Bong SHIN, Gunpo-si (KR); Il-Young HAN, Euiwang-si (KR); Min-Gyu KOH, Suwon-si (KR); Dong-Gil SHIM, Bucheon-si (KR); Dong-soo LEE, Cheonan-si (KR); Sang-Jean JEON, Hwaseong-si (KR)

(73) Assignee: SAMSUNG ELECTRONICS CO., LTD., Suwon-Si (KR)

(21) Appl. No.: 13/690,374

(22) Filed: Nov. 30, 2012

(30) Foreign Application Priority Data
Dec. 1, 2011 (KR) 10-2011-0127731

(51) Int. Cl. H05K 3/32

(52) U.S. Cl. CPC H05K 3/32
USPC 29/739

(57) ABSTRACT

A chip bonding apparatus configured to bond chips to a circuit board using induction heating generated by an AC magnetic field may be provided. In particular, the chip bonding apparatus includes at least one stage unit configured to support a circuit board on which a chip is placed, a rotating unit configured to rotatively move the at least one stage unit at a desired angle, and a bonding unit including an induction heating antenna configured to perform induction heating such the chip is bonded to the circuit board.

### CROSS-REFERENCE TO RELATED APPLICATION

This application claims priority under 35 U.S.C. §119 to Korean Patent Application No. 2011-0127731, filed on Dec. 1, 2011, in the Korean Intellectual Property Office, the entire disclosure of which is incorporated herein by reference.

### BACKGROUND

1. Field

Example embodiments relate to chip bonding apparatuses, and more particularly, to chip bonding apparatuses configured to bond and attach a chip to a board, and/or chip bonding methods using the same.

2. Description of the Related Art

Conventionally, a wire bonding method using a thin gold wire or a thin aluminum wire is widely used as a method of bonding an IC chip to a circuit board.

In such a wire bonding method, metallic pads used as input/output terminals are generally formed at the edges of an IC chip, e.g., a flip chip. As the density of the IC chip increases, the number of input/output terminals increases. Accordingly, intervals between the input/output terminals are reduced. Thus, the wire bonding method becomes more and more difficult to implement as the density of the IC chip increases.

In addition, as signal frequency is increased, noise can occur from the bonded wires, and thus electrical characteristics can be deteriorated.

To resolve the aforementioned difficulties of the wire bonding method, a flip chip bonding method is used. According to this method, an IC chip is bonded to a circuit board, for example, by forming solder bumps on a back surface of the IC chip and reflowing the solder bumps to be welded on the circuit board.

The conventional flip chip bonding method is achieved by bonding the solder bumps of an IC chip to metallic pads of a circuit board. For example, the solder bumps are formed on the IC chip, and after aligning the IC chip with the metallic pads on the circuit board, the IC chip and the circuit boards are heated by using an infrared light heating method or a convection heating method at a temperature that is higher than the welding point of the solder bumps such that the solder bumps are subject to a reflow, e.g., to be melted.

However, the conventional flip chip bonding method using an infrared light heating method or a convection heating method can apply heat on the IC chip and/or on the circuit board formed of, e.g., a polymeric material, up to a range of temperature between 200° C. and 300° C. in which a reflow of the solder bumps can occur. Accordingly, the polymer circuit board is vulnerable to heat, and thus is prone to be damaged by the heat.

To resolve the aforementioned difficulties of the conventional flip chip bonding method, a flip chip bonding method using induction heating is used.

However, the flip chip bonding method using induction heating poses an issue of a non-uniform intensity of an AC magnetic field, which is induced by a solenoid coil. Thus, uniform heat is not delivered to the solder bumps.

Further, a flip chip bonding apparatus using induction heating cannot process a large-area circuit board having tens of the IC chips. Thus, it is difficult to reduce a process time under certain limit.

### SUMMARY

Therefore, example embodiments provide a chip bonding apparatus configured to form an AC magnetic field, and capable of bonding a chip to a circuit board through induction heating by an AC magnetic field, and of performing a process of cooling the circuit board that is bonded, and a chip bonding method using the same.

According to example embodiments, a chip bonding apparatus may include at least one stage unit, a rotating unit, and a bonding unit. The one stage unit may be configured to support a circuit board on which a chip is placed. The rotating unit may be configured to rotatively transfer the at least one stage unit at a desired (or alternatively, predetermined) angle. The bonding unit may include an induction heating antenna that is configured to perform induction heating such that the chip is bonded to the circuit board.

The chip may include a solder bump and a surface of the solder bump is configured to be bonded to the circuit board. The induction heating antenna may be configured to perform induction heating on the solder bump. The at least one stage unit may include a plurality of stages configured to support the circuit board, and a base at a lower portion of the plurality of stages to support the plurality of stages.

Each of the plurality of stages may include an adsorption panel including adsorption holes defined therein. The adsorption hole may be configured to hold the circuit board using a vacuum.

The adsorption panel may further include a nitrogen supplying/discharging hole defined therein and configured to at least one of supply and discharge nitrogen. The adsorption panel may be formed of one of at least one of Invar™ (a nickel iron alloy generically known as containing 36% of nickel), graphite, and silicon carbide.

Each of the plurality of stages may include a heat insulation panel, which is configured to retain heat.

At least one of the plurality of stages and the base may include an elastic unit located connected thereto.

The at least one stage unit may include a plurality of stage units. The plurality of stage unit may be located at a number of positions on the rotating unit and spaced apart from one another at intervals. The number of positions may be equal to the number of the plurality of stage units.

The bonding unit may include a chamber. The chamber may include an opening and house the induction heating antenna therein. The bonding unit may be configured to be closed by the at least one stage unit, as the at least one stage unit moves toward the opening of the chamber.

The induction heating antenna may include a spacer and a contamination preventing panel at a lower surface thereof. The spacer may be configured to maintain a distance between the at least one stage unit and the induction heating antenna when in a case of bonding the chip. The contamination preventing panel may be configured to cover the circuit board on the stage unit to prevent foreign substance, which is generated in a case of bonding the chip, from contaminating the induction heating antenna.

The chip bonding apparatus may further include a loading unit, an unloading unit and a cooling unit. The loading unit may be configured to load the circuit board, on which the chip is placed, on the at least one stage unit. The unloading unit may be configured to unload the circuit board having the chip bonded thereto from the at least one stage unit. The cooling unit may be configured to cool the at least one stage unit from which the circuit board having completed the bonding completed is unloaded.

The cooling unit may include a chamber configured to contain cooling water.

According to example embodiments, a chip bonding method may include loading a circuit board, on which a chip is placed, on a stage unit of a chip bonding apparatus, inductively heating the chip to be bonded to the loaded circuit board, first cooling the loaded circuit board after completing the bonding, unloading the circuit board from the stage unit, and second cooling the stage unit after unloading the circuit board.

The chip bonding method described herein may further include rotating at a desired (or alternatively, predetermined) angle the stage unit loaded with the circuit board to a first position corresponding to the bonding unit, and moving the stage unit to a second position at the bonding unit.

The chip bonding method described herein may further include moving the stage unit to be separated from the bonding unit after completing the bonding, rotating the stage unit is separated from the bonding unit, and cooling the circuit board at a room temperature after rotating the stage unit.

The chip bonding method described herein may further include rotating the stage unit at a desired (or alternatively, predetermined) angle such that the stage unit is moved to a position corresponding to a cooling unit of the chip bonding apparatus after unloading the circuit board from the stage unit, and moving, e.g., ascending, the stage unit to contact the cooling unit such that the stage unit is cooled.

According to example embodiments, an AC power may be applied to an induction heating antenna of the chip bonding apparatus to form the AC magnetic field. Using this AC magnetic field, a chip and a circuit board may be more uniformly heated. Thus, a problem of a chip bonding process, e.g., a partial burning of a circuit board by the induction of non-uniform magnetic field may be prevented.

In addition, by having a jig-jag type plane panel antenna, an area of which is larger than a large-area circuit board, tens of chips may be bonded at once, and thus the processing time may be substantially reduced.

In addition, by connecting a balance capacitor to an antenna, an arc phenomenon that may occur in the antenna and the circuit board may be prevented.

According to example embodiments, a chip bonding apparatus may include at least one stage unit and a bonding unit. The at least one stage unit may be configured to support a circuit board on which a chip is placed and configured to be movable among various positions. The bonding unit may include an induction heating antenna. The bonding unit may be configured to bond the chip to the circuit board using a heat induced by the induction heating antenna and configured to be closed by the at least one stage unit while maintaining a distance between the induction heating antenna and the at least one stage unit.

The bonding unit may include a high conductivity metallic structure surrounding the induction heating antenna. The high conductivity metallic structure at surroundings may be configured to modulate an intensity of an AC magnetic field induced by the induction heating antenna, for instance, to be more uniform.

The at least one stage unit may include a nitrogen supplying/discharging unit configured at least one of to provide and to eliminate nitrogen atmosphere.

The bonding unit may further include at least one balance capacitor. The at least one balance capacitor may be configured to be connected to the induction heating antenna such that an arcing between the induction heating antenna and the circuit board is suppressed.

The at least one balance capacitor may include a first balance capacitor connected to one side of the induction heating antenna, and a second balance capacitor connected between the other side of the induction heating antenna and a ground.

### BRIEF DESCRIPTION OF THE DRAWINGS

These and/or other aspects of the inventive concepts will become apparent and more readily appreciated from the following description of the example embodiments, taken in conjunction with the accompanying drawings of which:

FIG. 1 is a cross-sectional view schematically showing a chip and a circuit board for which a chip bonding apparatus according to example embodiments is used.

FIG. 2 is a perspective view of a chip bonding apparatus according to example embodiments.

FIG. 3 is a front view of a chip bonding apparatus according to example embodiments.

FIGS. 4 to 5 are perspective views showing a stage unit of a chip bonding apparatus according to example embodiments.

FIG. 6 is a perspective view showing a bonding unit according to example embodiments.

FIG. 7 is a perspective view of an induction heating antenna located at an inside of a bonding unit according to example embodiments.

FIG. 8 is a cross-sectional view schematically showing a motion of a spacer of an induction heating antenna according to example embodiments, taken along line A-A′ of FIG. 7.

FIG. 9 is a perspective view illustrating the induction heating antenna of FIG. 7.

FIG. 10 is a mimetic diagram illustrating a state of bonding a chip to a circuit board by using the induction heating antenna of FIG. 9.

FIG. 11 is a perspective view illustrating an induction heating antenna according to example embodiments.

FIG. 12 is a graph illustrating a uniformity enhancement of an AC magnetic field, which is generated at the induction heating antenna of FIG. 11.

FIG. 13 is a circuit diagram of a chip bonding apparatus having the induction heating antenna of FIG. 11 at its center.

FIG. 14 is a flow chart showing a bonding method using a chip bonding apparatus according to example embodiments.

### DETAILED DESCRIPTION

Example embodiments will now be described more fully with reference to the accompanying drawings. Example embodiments may, however, be embodied in many different forms and should not be construed as being limited to the embodiments set forth herein; rather, these embodiments are provided so that this disclosure will be thorough and complete, and will fully convey the concept of example embodiments to those of ordinary skill in the art. In the drawings, the thicknesses of layers and regions are exaggerated for clarity. Like reference numerals in the drawings denote like elements throughout, and thus their description will be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The terminology used herein is for the purpose of describing a particular embodiment only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. Thus, the regions illustrated in the figures are schematic in nature and their shapes are not intended to illustrate the actual shape of a region of a device and are not intended to limit the scope of example embodiments. It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Unless otherwise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

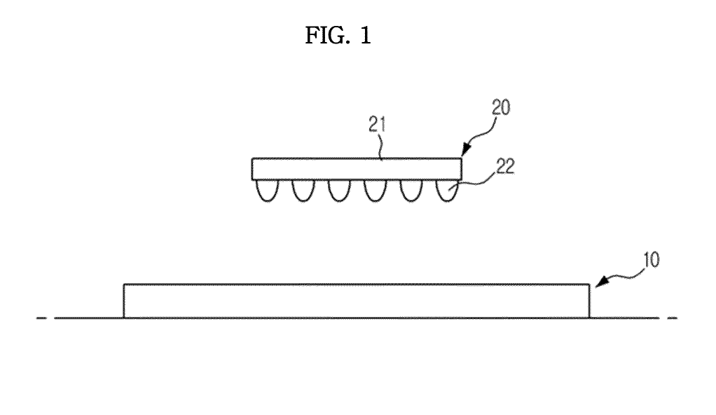

FIG. 1 is a cross-sectional view schematically showing a chip and a circuit board for which a chip bonding apparatus according to example embodiments is used.

Referring to FIG. 1, a chip bonding apparatus may be an apparatus configured to have a flip chip 20 adhesively attached to a circuit board 10. The flip chip 20 may include a die 21 formed in the shape of a plane panel, and a plurality of solder bumps 22 protrudedly formed from one surface of the die 21 so that the die 821 may be mounted on the circuit board 10.

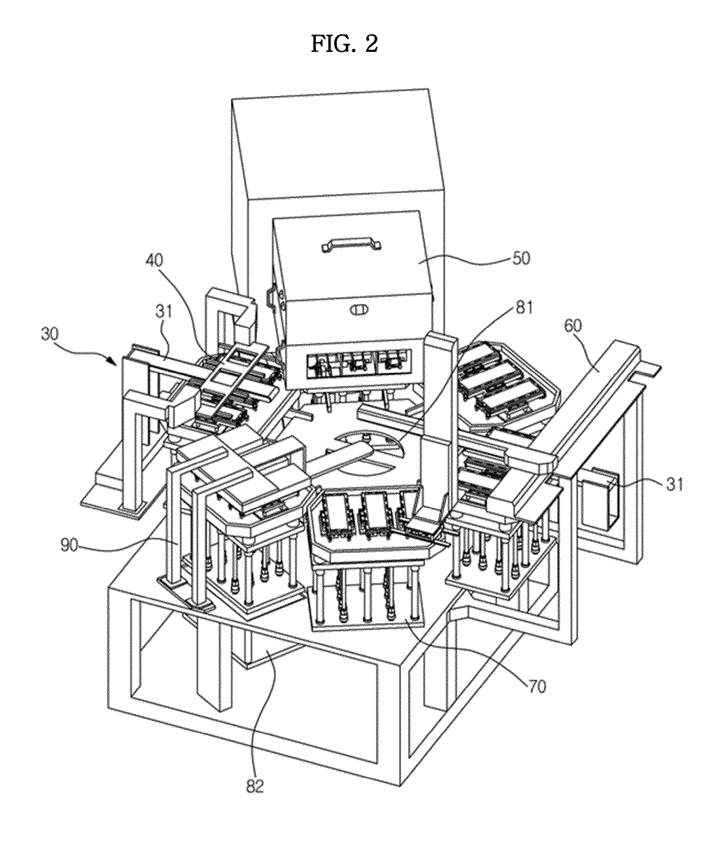

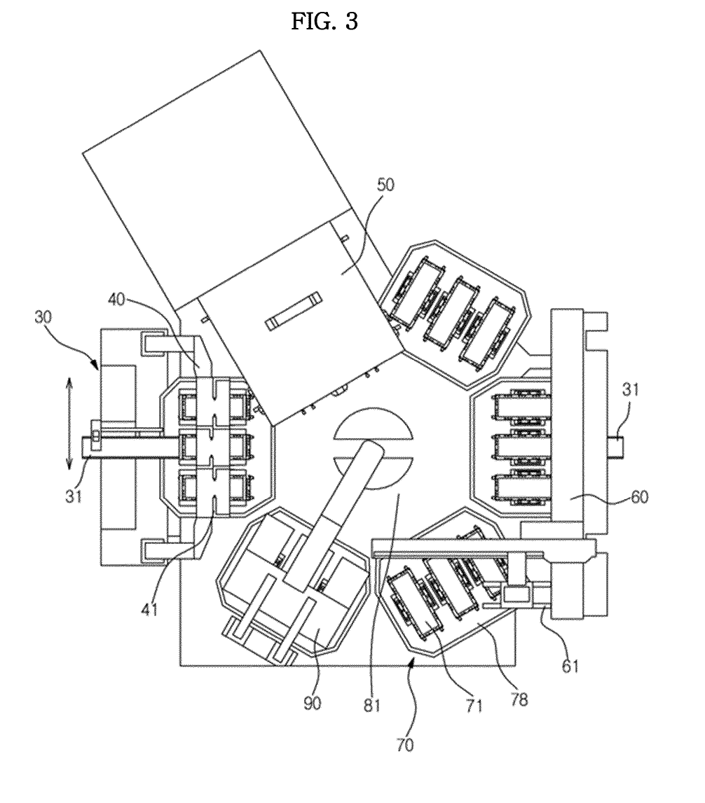

FIG. 2 is a perspective view of a chip bonding apparatus according to example embodiments. FIG. 3 is a front view of a chip bonding apparatus according to example embodiments. Referring to FIGS. 2 and 3, a chip bonding apparatus may include a transfer unit 30, a stage unit 70, a loading unit 40, a bonding unit 50, an unloading unit 60, a cooling unit 90, and a rotating unit. The transfer unit 30 may be configured to transfer, e.g., charge and discharge, the circuit board 10, on which the flip chip 20 is placed, to and from the chip bonding apparatus. On the stage unit 70, the circuit board 10, on which the flip chip 20 is placed, may be loaded. The loading unit 40 may be configured to load the circuit board 10 on the stage unit 70 when the circuit board 10 transferred by the transfer unit 30 is held. The bonding unit 50 may be configured to bond the flip chip 20 to the circuit board 10. The unloading unit 60 may be configured to discharge the circuit board 10 having completed a bonding process at the stage unit 70 to the transfer unit 30, which is configured to discharge the circuit board 10 to an outside. The cooling unit 90 may be configured to lower the temperature of the heated stage unit 70. The rotating unit 81 may be configured to rotatively move the stage unit 70 at a desired (or alternatively, predetermined) angle.

The transfer unit 30 may include a conveyor 31 and a motor. The conveyor 30 may be configured to transfer the circuit board 10 when the circuit board 10, on which the flip chip 20 is placed, is placed on the conveyor 31. The motor (not shown) may be configured to move the conveyor 31, for example, to left and right. The loading unit 40 may include a plurality of holders 41 aligned in a parallel manner, and configured to hold the circuit board 10 delivered from the transfer unit 30.

When the circuit board 10 having the flip chip 20 thereon is placed on the conveyor 31, the conveyor 31 may start to operate to deliver the circuit board 10 to one of the plurality of holders 41 of the loading unit 40. Referring to FIG. 3, after delivering the circuit board 10 to a holder 41 among the plurality of holders 41 aligned in a parallel manner, the transfer unit 30 may move the conveyor 31 to a position corresponding to a next holder 41 so that another circuit board 10 may be delivered to a next holder 41.

When the delivery of the circuit board 10 to the holder 41 of the loading unit 40 is completed, the stage unit 70 configured to receive the circuit board 10 thereon, may move to a position corresponding to the loading unit 40. The holder 41 of the loading unit 40 may place the circuit board 10 held by the holder 41, onto the stage unit 70.

The transfer unit 30 may include a supplying unit configured to deliver the circuit board 10 having the flip chip 20 thereon to the loading unit 40 using the conveyor 31, and a discharging unit configured to discharge the circuit board 10 having completed a bonding process. When the circuit board 10 having completed a bonding process is placed on the conveyor 31 by the unloading unit 60, the discharging unit may discharge the circuit board 10 to an outside of the chip bonding apparatus by driving the conveyor 31.

When the circuit board 10 is supplied to the chip bonding apparatus and the flip chips is attached, e.g., bonded, to the circuit board 10, a different apparatus may be used to discharge the circuit board 10 having completed with the bonding from the chip bonding apparatus. The different apparatus may also be used to constitute the transfer unit 30 other than the conveyor 31.

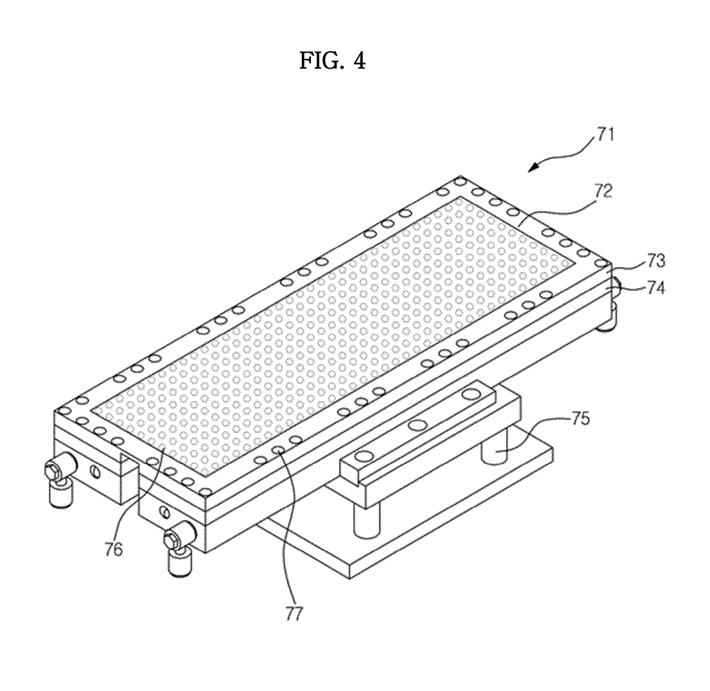

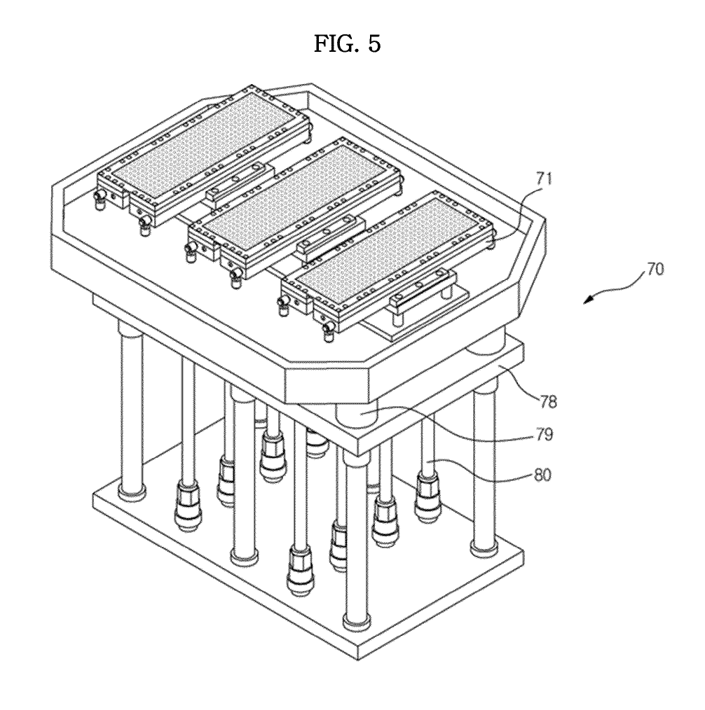

FIGS. 4 to 5 are perspective views showing a stage unit of a chip bonding apparatus according to example embodiments.

On the stage unit 70, the circuit board 10 loaded from the loading unit 40 may be placed.

The stage unit 70 may include a plurality of stages 71 having the circuit board 10 thereon, a base 78 configured to support the plurality of stages 71, and various lines 80 configured to supply and discharge gases, e.g., nitrogen to supply the adsorption force for hold the circuit board 10.

The stage 71 may include an adsorption panel 72 configured to support the circuit board 10 to be placed thereon, a flow path forming panel 73 configured to support the adsorption panel 72 and provided with various flow paths formed therein, and an heat insulation panel 74 configured to block heat delivery.

The adsorption panel 72 may be provided with a plurality of holes on a surface thereof, and the holes formed on a surface of the adsorption panel 72 may be composed of an adsorption hole 76, at least one N₂ supplying/discharging hole 77. For example, some of the at least one supply/exhaust hole 77 may be used to supply N₂ and some of the at least one supply/exhaust hole 77 may be used to discharge N₂. Accordingly, the at least one N₂ supplying/discharging hole 77 will be referred to as a N₂ supplying hole or a N₂ discharging hole herein below, depending circumstances.

The adsorption hole 76 may be connected to a vacuum pump through a bypass piping provided with a valve to perform a vacuum chucking. If a bonding process is performed when the circuit board 10 is not firmly attached to the stage 71, the circuit board 10 may be severely deformed due to a rapid temperature increase during the bonding process. The deformed circuit board may even contact an induction heating antenna 52 of the chip bonding apparatus, and thereby causing an arc. Further, the circuit board 10 may be burned, or the flip chips 20 placed on the circuit board 10 may fly away.

To resolve the aforementioned issues, the adsorption hole 76 according to example embodiments may be formed on the adsorption panel 72 such that the circuit board 10 is adsorptively attached to the adsorption panel 72 using vacuum intake force at the adsorption hole 76. Thus, aforementioned problems, e.g., bending of the circuit board 10 while being heated, may be prevented or minimized in advance.

The N₂ supplying hole 77 may be connected to a N₂ supply line 80 to supply nitrogen when a bonding process is performed. Accordingly, when the boding process is performed, the atmosphere may be turned into a nitrogen atmosphere. The solder bumps 22 of the flip chips 20, which are to contact the circuit board 10, may be processed with a chemical material referred to as flux.

The flux is defined as a solvent processed on a surface of metal to prevent the surface of the metal, when the whole or a part of which is melted, from being oxidized by reacting to air. If the surface of the metal is melted during a bonding process, an oxidized substance layer may be formed. Thus, a quality bonding may be difficult to achieve. Accordingly, to prevent or reduce an oxidation of the surface of metal, the flux may be processed on the surface of the metal.

However, in a high temperature bonding process, the flux may be vaporized. Accordingly, the solder bumps 22 contacting the circuit board 10 may be oxidized, and thus a bonding process may not be performed properly. To resolve this problem, the atmosphere, in which the bonding process is performed, may be turned into a nitrogen atmosphere.

The N₂ discharging hole 77, by in-taking and discharging the supplied nitrogen may eliminate the nitrogen atmosphere.

The adsorption hole 76 may be formed at a central domain of the adsorption panel 72, on which the circuit board 10 is placed, and the N₂ supplying hole 77 and the N₂ discharging hole 77 may be formed at an outer portion of the adsorption panel 72.

The adsorption panel 72 may be formed of at least one of Ni, Invar™ (known as a compound metal of Fe, Graphite), and SiC. When a bonding process is performed, the heat generated at the solder bumps 22 may be rapidly delivered to the relatively cold circuit board 10, which is in contact with the solder bumps 22.

Thus electrical connections at the point of contact between the solder bumps 22 and the circuit board 10 may not be properly formed. Thus, to resolve this problem, example embodiments may form the adsorption panel 72 using a material having superior heat generating characteristics and less deformation characteristics, e.g., at least one of Ni, Invar™, Graphite, and Sic.

The flow path forming panel 73 may be located at a lower surface of the adsorption panel 72 and include a flow path configured to support the adsorption panel 72. The flow path may be configured to be connected to various holes formed at the adsorption panel 72. The heat insulation panel 74 may be located at a lower surface of the flow path forming panel 73, and is configured to prevent the melting efficiency of the solder bumps 22 from falling because the heat generated during a bonding process may escape to an outside through the stage 71.

At a lower surface of the stage 71, a first elastic unit 75 may be located. The first elastic unit 75 may be a structure that, when a force is applied from an outside, the shape thereof is changed, and when the force is removed, the shape thereof is returned to the original shape. For example, a spring may be used as the first elastic unit 75.

When the stage unit 70 having loaded with the circuit board 10 is ascended and is moved to the position having a certain interval with respect to the induction heating antenna 52, the stage unit 70 may be additionally ascended to seal the bonding unit 50.

As the stage unit 70 is additionally ascended, the open lower surface of the bonding unit 50 and the base 78 of the stage unit 70 are closely adhered to each other. Thus, the bonding unit 50 may be sealed.

When the additional ascending force, which is applied to the stage unit 70 to seal the bonding unit 50, is delivered to the first elastic unit 75, the first elastic unit 75 may be compressed. To the extent that the first elastic unit 75 is compressed, the stage unit 70 may be additionally ascended.

While the additional ascension of the stage unit 70 to seal the bonding unit 50 is performed by compressing the first elastic unit 75, the certain interval in between the induction heating antenna 52 and the stage 71 may not be affected, because the interval is maintained by the spacer 55 for a uniform bonding.

At a lower surface of the stage 71, the base 78 configured to support the stage 71 may be located. The base 78 may be designed to have a same area as the area of an open lower surface of the bonding unit 50, and/or to have a same shape as the shape of the open lower surface of the bonding unit 50. Accordingly, when the stage unit 70 is ascended, the open lower surface of the bonding unit 50 may be closely adhered to the base 78 of the stage unit 70.

When the base 78 of the stage unit 70 and the open lower surface of the bonding unit 50 are closely adhered, the bonding unit 50 may be sealed. At a lower surface of the base 78 (which is located at a lower surface of the stage 71) a second elastic unit 79 may be located. The second elastic unit 79 may be configured to perform the same role as the first elastic unit 75 located at the lower surface of the stage 71. The second elastic unit 79 may also be configured to cause a vertical tilting of the base 78. Thus, a certain room may be given to the movement of the base 78.

At a lower surface of the base 78, the various lines 80 may be located. The various lines 80 may include vacuum lines configured to supply adsorption force through the adsorption hole 76 of the adsorption panel 72 of the stage 71, N₂ supplying lines configured to supply N₂ through the N₂ supplying hole 77 of the adsorption panel 72, and N₂ exhaust lines configured to exhaust the supplied N₂.

The stage unit 70, while having a number of intervals that are divided as many as the number of the plurality of units thereof, may be located on the rotating unit 81. By rotating the rotating unit 81, the stage unit 70 may be passed through each set process. The stage unit 70 may be connected to an upper driving unit 82 composed of a transfer screw and a motor, which are located at a lower portion of the rotating unit 81. Thus, the stage unit 70 may move vertically such that the interval in between the circuit board 10 loaded at the stage 71 and the induction heating antenna 52 of the bonding unit 50 is adjusted.

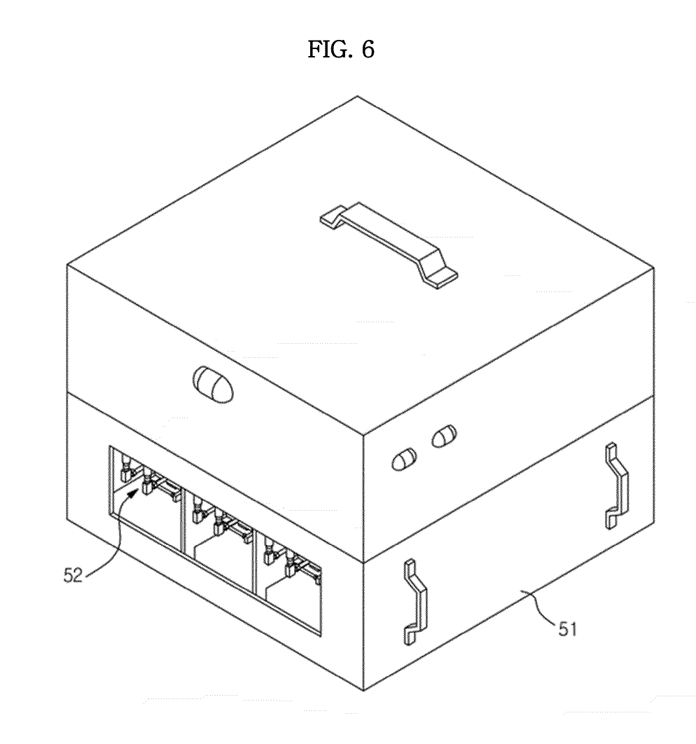

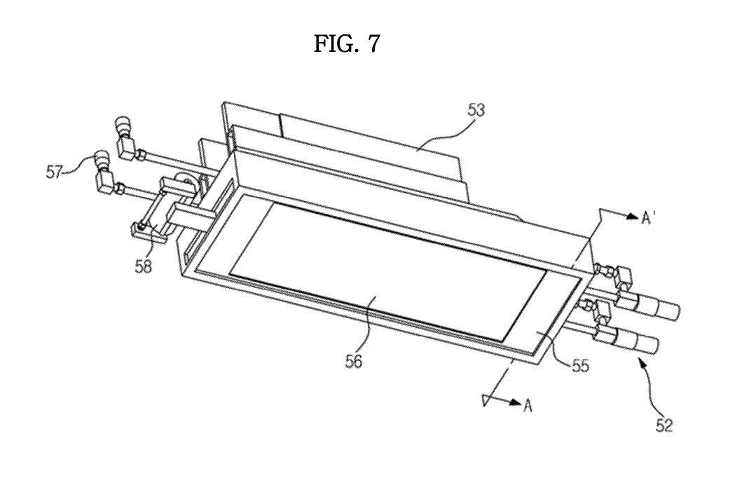

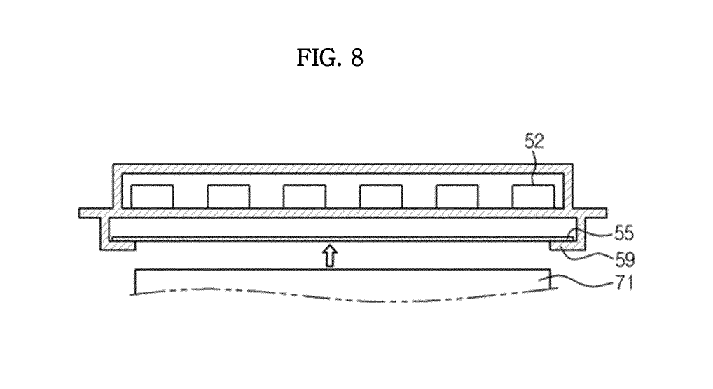

FIG. 6 is a perspective view showing a bonding unit according to example embodiments. FIG. 7 is a perspective view of an induction heating antenna located at an inside of a bonding unit according to example embodiments. FIG. 8 is a cross-sectional view schematically showing a motion of a spacer of an induction heating antenna according to example embodiments, taken along line A-A′ of FIG. 7.

The bonding unit 50 may include a chamber 51, and a plurality of induction heating antennas 52 provided at an inside of the chamber 51.

The chamber 51 may cover electromagnetic wave, and have an open lower surface. When the stage unit 70 is moved in an ascending manner through the open lower surface of the chamber 51 so that the base 78 of the stage unit 70 and the lower surface of the chamber 51 are closely adhered to each other, the chamber 51 may be sealed. When the chamber 51 is sealed, an induction heat generated by the induction heating antenna 52 may be provided at an inside the chamber 51. Accordingly, the solder bumps 22 of the flip chips 20 may be melted, and thus the flip chips 20 may be bonded to the circuit board 10.

The induction heating antenna 52 may be provided at an inside of the chamber 51. To bond the flip chips 20 to the circuit board 10, the flip chips 20 may be induction-heated. The induction heating antenna 52 arranged between a supporting unit 53 may be located at an inner side surface of an upper portion of the chamber 51. The supporting unit 53 may be a plurality of supporting units 53 such that the induction heating antenna 52 may be sufficiently fixed.

At a lower surface of the induction heating antenna 52, the spacer 55 may be located. The spacer 55 may be located at both ends of a lower surface of the induction heating antenna 52. When the stage 71 loaded with the circuit board 10 approaches the induction heating antenna 52, the spacer 55 may enable the stage 71 to maintain a certain interval with respect to the induction heating antenna 52.

Referring to FIG. 8, the spacer 55 may be supported by a holder 59 at a position spaced apart from the induction heating antenna 52 by a desired (or alternatively, predetermined) distance. Accordingly, when the stage 71 is ascended as pushing the spacer 55 toward an upper direction to its maximum extent until the ascension of the spacer 55 is no longer possible, the induction heating antenna 52 and the stage 71 may be provided with an interval as wide as the thickness of the spacer 55.

The spacer 55 may be formed of a material that is resistant to a deformation at a high temperature. For example, the spacer 55 may be formed of a material that can endure at a high temperature, e.g., ceramic or engineering plastic. Thus, an eddy current generated by the magnetic field formed at the surroundings of the induction heating antenna 52 may not flow through the spacer 55. The width of the end surface of the spacer 55, which determine the interval between the induction heating antenna 52 and the circuit board 10 (or alternatively, the stage 71), may be designed based on considerations for an efficient and uniform bonding.

Further, at the lower surface of the induction heating antenna 52, a contamination preventing panel 56 may be located. The contamination preventing panel 56 may be designed to cover the board. For example, the contamination preventing panel 56 may be located at the lower surface of the induction heating antenna 52, and has a concave shape in a direction from the lower surface to an upper surface, e.g., a shape of a lid.

The contamination preventing panel 56 may be attached at the induction heating antenna 52 and prevent (or minimize) the induction heating antenna 52 from being contaminated by the flux, which may be vaporized during a bonding process. Because the contamination preventing panel 56 covers the circuit board as a lid, the nitrogen supplied through the N₂ supplying hole 77 of the adsorption panel 72 of the stage 71 may stay at a space in between the board and the contamination preventing panel 56. Thus, a bonding process may be performed in nitrogen atmosphere.

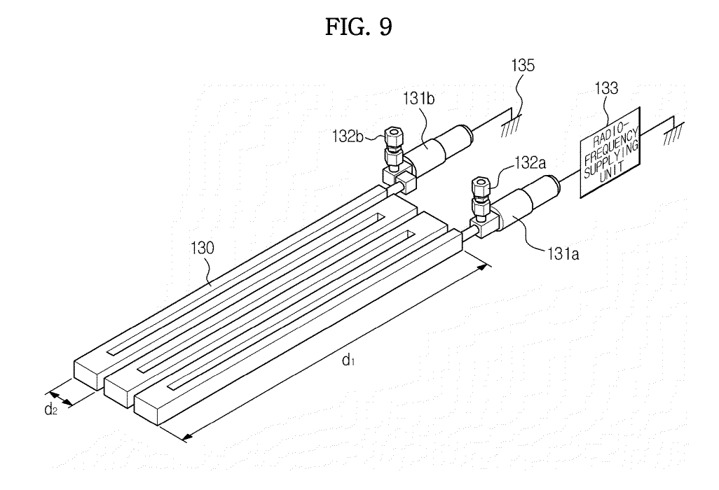

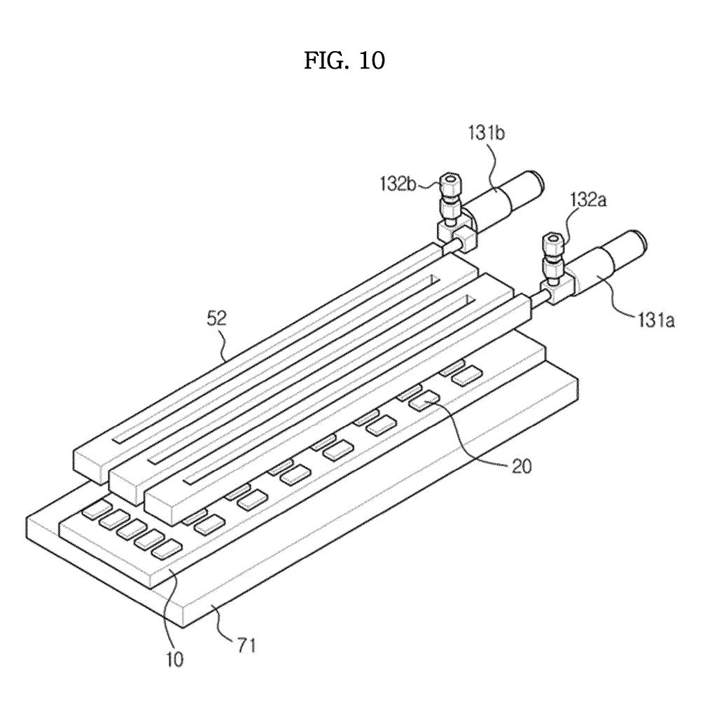

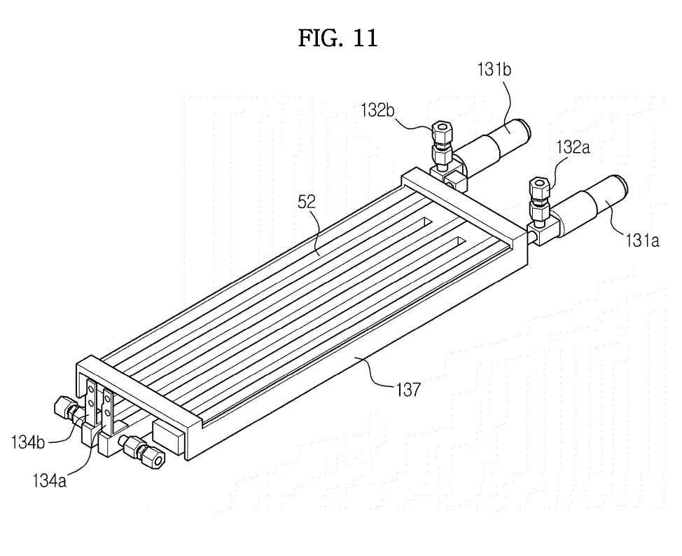

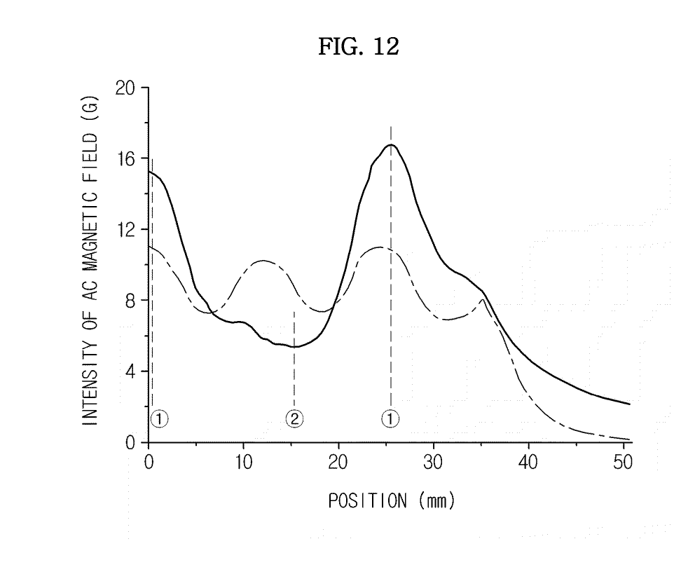

FIG. 9 is a perspective view illustrating the induction heating antenna of FIG. 7. FIG. 10 is a mimetic diagram illustrating a state of bonding a chip to a circuit board by using the induction heating antenna of FIG. 9. FIG. 11 is a perspective view illustrating an induction heating antenna according to example embodiments. FIG. 12 is a graph illustrating a uniformity enhancement of an AC magnetic field, which is generated at the induction heating antenna of FIG. 11.

Referring to FIG. 9, the induction heating antenna 52 may have a shape of a plane panel, and each bending portion thereof may be provided with about a 90° angle. Further, the induction heating antenna 52 may be provided with a jig-jag pattern, and an interval ‘d1’, e.g., a length between the bending portions of the induction heating antenna 52 at opposite ends and an line interval ‘d2’, e.g., a width at the bending portion of the induction heating antenna 52 may be structured in a constant manner throughout the induction heating antenna 52. For example, the interval ‘d1’ and the line interval ‘d2’ may be adjusted so that the uniformity and the B-field magnitude induced from the induction heating antenna 52 is optimized.

While the induction heating antenna 52 having a jig-jag pattern is described as one example, the induction heating antenna 52 having a spiral pattern or a pattern composed of a plurality of concentric circles, which is capable of forming an AC magnetic field, may also be included in the scope of the present inventive concepts.

In addition, the width and the length of the induction heating antenna 52 may be larger than or same as the width and the length of the circuit board 10. Accordingly, the plurality of flip chips 20 on the circuit board 10 may be designed such that a bonding process is performed by heating the plurality of flip chips 20 on the circuit board 10 at once.

If the induction heating antenna 52 is larger than or same as the size of the circuit board 10, the large-area circuit board 10 may be heated at once. Thus, compared with a conventional bonding process of transferring the circuit board having the flip chips 20 thereon in a single direction and applying heat to each (or a group) of the flip chips 20 individually, the process time may be substantially reduced.

The induction heating antenna 52 may be composed of a metallic material, e.g., copper Cu plated with silver Ag. Other materials having a high conductivity also may be used as a material for the induction heating antenna 52.

The induction heating antenna 52 may further include a radio-frequency supplying unit 133, and connecting terminals 131a and 131b configured to be connected to a ground135. The connecting terminals 131a and 131b may be positioned at one side surface of the induction heating antenna 52, and may be a cylindrical terminal.

The radio-frequency supplying unit 133 may include a radio-frequency generating unit (not shown) that generates a high-frequency AC power at about 27,12 MHz or about 13.56 MHz, and a matching unit (not shown) that generates impedance between the radio-frequency generating unit (not shown) and the induction heating antenna 52.

To cool the induction heating antenna 52 heated by the high-frequency AC power, cooling water ports 132a and 132b may be further included. The cooling water ports 132a and 132b may be connected to a cooling line 57 configured to supply cool water, and composed of inlet and outlet ports.

Referring to FIG. 10, to attach the flip chips 20 to the circuit board 10, the circuit board 10 having the plurality of flip chips 20 thereon, the flip chips 20 being provided with a certain interval therebetween, may be disposed at a lower portion of the induction heating antenna 52, while being spaced apart from the lower portion of the induction heating antenna by a desired (or alternatively, predetermined) interval.

The desired (or alternatively, predetermined) interval may be narrow so that sufficient heating may be performed using the induction heating antenna 52. For example, the desired interval may be about 2 mm to 3 mm.

When the circuit board 10 having a number of the flip chips 20 placed thereon, the flip chips 20 being provided with a certain distance therebetween, is disposed at a lower portion of the induction heating antenna 52 and a radio-frequency AC power is applied to the circuit board 10 and the flip chips 20, the flip chips 20 may be attached, e.g., bonded to the circuit board 10. The bonding principle of the flip chips 20 using the induction heating antenna 20 is as follows.

When the radio-frequency AC power is applied to the induction heating antenna 52 and generates an electric current through the induction heating antenna, a magnetic field is formed at the surroundings of the induction heating antenna 52. At this time, if a metal is present near the induction heating antenna 52, an eddy current generated by the magnetic field flows through and thus heats the metal. This induction heating is specifically a heating of a metal using an eddy current.

Example embodiments use the above principle. For example, the circuit board 10 having the flip chips 20 thereon may be disposed at a lower portion of the induction heating antenna 52. By applying a radio-frequency AC power to the induction heating antenna 52, an AC magnetic field is formed at the surroundings of the induction heating antenna 52. The AC magnetic field induces an eddy current at the solder bumps 22, the solder bumps 22 are heated by the eddy current, and thus the flip chips 20 are attached to the circuit board 10.

Referring to FIG. 11, the induction heating antenna 52 according to example embodiments may further include a metallic edge 135. To be spaced apart from the induction heating antenna 52 by a certain distance, the metallic edge 135 may be attached at the surroundings of the induction heating antenna 52 by a supporting unit (not shown).

To bond a number of the flip chips 20 on the circuit board 10 at once, the intensity of the AC magnetic field needs to be uniform. If not uniform, a side receiving relatively intense the AC magnetic field may be burned, while the other sides receiving less intense AC magnetic field may achieve a poor bonding quality.

To form more uniform AC magnetic field at the induction heating antenna 52, more of the metallic edge 135 is prepared.

The metallic edge 135 may have a closed-channel shape that an upper surface and a lower surface of the induction heating antenna 52 are exposed. For example, the metallic edge 137 may be configured to wrap around the edges of the induction heating antenna 52, while exposing the upper surface and the lower surface of the induction heating antenna 52.

The metallic edge 135 may be composed of copper Cu. Other metals having a high conductivity also may be used as a material for the metallic edge 137.

FIG. 12 is a graph illustrating the intensity distributions of the AC magnetic field, comparing one case where the metallic edge 135 is located at the induction heating antenna 52 and another case where the metallic edge 135 not located at the induction heating antenna 52. As illustrated in FIG. 12, in the case where the metallic edge 135 is not located at the induction heating antenna 52 (shown in solid line), the intensity of the AC magnetic field somewhat varies by the position of the induction heating antenna 52. For example, at one position (shown as \hat{1}) where the intensity of the AC magnetic field is relatively strong, the intensity of the eddy current induced by the AC magnetic field is also strong, and thus during a metal wiring or bonding process the flip chips 20 to the circuit board 10 overheating phenomenon may occur. Because the intensity of the AC magnetic field is relatively weak at another position (shown as \hat{2}), the intensity of the induced eddy current is weak, and thus the solder bumps 22 on the flip chip 20 may not be sufficiently heated for a metal wiring or bonding process.

In the case where the metallic edge 135 is located at the induction heating antenna 52 (shown in dot-and-dash line), the uniformity of intensity of the AC magnetic field at the surroundings of the induction heating antenna 52, when compared to the case when the metallic edge 137 is not located, is improved. The reason for the improved uniformity of the AC magnetic field is as follows.

By providing a metallic edge 137 having high conductivity at the surroundings of the induction heating antenna 52, a current may be induced at the metallic edge 137 in an opposite direction compared to the direction of the current flowing at the induction heating antenna 52. By the induction current induced at the metallic edge 137, an induction magnetic field is formed in an opposite direction to the magnetic field formed by the induction heating antenna 52. This additional induction magnetic field offsets or a reinforces the current magnetic field formed at the induction heating antenna 52, and thus the uniformity of the intensity of the AC magnetic field at the surroundings of the induction heating antenna 52 is improved.

In the case where the metallic edge 137 is not located, the magnetic field at an edge portion of the induction heating antenna 52 may become excessively strong. To prevent or minimize this edge effect from occurring, the larger induction heating antenna 52 may be manufactured. Due to the increase of impedance, however, the larger induction heating antenna 52 may experience a difficulty in impedance matching.

According to example embodiments, the occurrence of the edge effect is prevented or minimized by providing the metallic edge 137 at the edges of the induction heating antenna 52. Accordingly, the uniformity of the intensity of the AC magnetic field may be substantially improved.

Thus, the plurality of flip chips 20 placed on the large-area circuit board 10 may be bonded at once, and the defective chip bonding and/or an overheating of the circuit board 10 may be prevented or minimized.

As described earlier, the circuit board 10 and the induction heating antenna 52 may be provided with a narrow interval (e.g., about 2 mm to about 3 mm) therebetween, and the AC power applied to the induction heating antenna 52 may be a radio-frequency power at about 27.12 MHz or about 13.56 MHz.

Thus, when current flows as radio-frequency AC power is applied to the induction heating antenna 52, a voltage is generated at the desired (or alternatively, predetermined) interval between the circuit board 10 and the induction heating antenna 52, thereby generating an arc. As is generally known, an arc is an electric light having a ring shape and generated between two electrodes.

Two arcs may be formed at the induction heating antenna 52 and the circuit board 10, at which voltages may be generated.

To prevent or reduce the arc issues described above, the distance between the induction heating antenna 52 and the circuit board 10 may be increased to decrease the intensity of the eddy current induced by the AC magnetic field. According to this method, a heating efficiency of the chip bonding apparatus may be decreased, thereby increasing the process time.

According to example embodiments, to prevent or minimize an arc phenomenon while maintaining the interval between the induction heating antenna 52 and the circuit board 10, a balance capacitor 58 may be connected to the induction heating antenna 52.

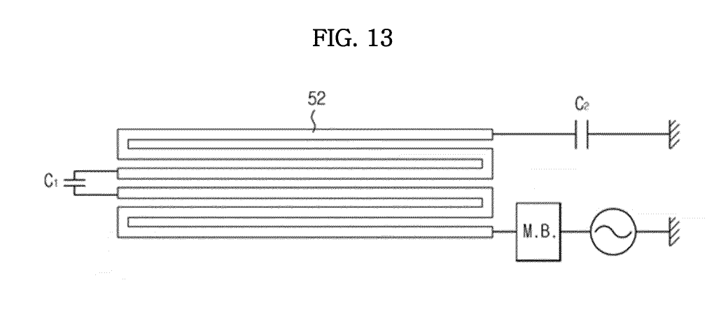

FIG. 13 is a circuit diagram of a chip bonding apparatus having the induction heating antenna of FIG. 11 at its center. Referring to FIG. 13, terminals 134a and 134b configured to connect the balance capacitor 58 to one side surface of the induction heating antenna 52 may be prepared.

Referring to FIGS. 7 and 9, the terminals 134a and 134b of the balance capacitor 58 may be disposed at a central portion of a side surface of the induction heating antenna 52, and the connecting terminals 131a and 131b to which a ground 135 and the AC power 134 is applied may be disposed at another side surface of the induction heating antenna 52, which is opposite to the one side surface.

Referring to FIG. 11, as a circuit diagram of the induction heating antenna 52 may be provided with two balance capacitors C1 and C2 connected thereto.

For example, the first balance capacitor C1 may be connected to the both connecting terminals 134a and 134b of the balance capacitor, and the second capacitor C2 may be connected to the connecting terminal 131b, which is connected to a ground 135.

For example, at one side surface of the induction heating antenna 52, the first balance capacitor C1 may be connected, while at another side surface of the induction heating antenna 52, the second balance capacitor C2 may be connected to a ground 135. Further, at the another side surface, a matching box configured to match the impedance between the AC power of radio-frequency, the induction heating antenna 52, and the radio-frequency AC power may be provided.

For example, the balance capacitor C1 and C2 may be vacuum capacitors provided with capacitive impedances. The balance capacitor C1 and C2 may be connected to the induction heating antenna 52 to decrease the overall impedance of the induction heating antenna 52. Accordingly, the voltage, which is resulted from the radio-frequency AC power being applied, may be decreased, thereby preventing or minimizing a risk of an arc generation.

The capacity of the first balance capacitor C1 and the second balance capacitor C2 may be adjusted, by considering the impedance of the induction heating antenna 52, such that the risk of an arc generating is sufficiently deceased.

Herein below, the description of a remaining structure of the chip bonding apparatus is revisited.

The unloading unit 60 may unload the circuit board 10, which is completed a bonding at the bonding unit 50 and passed through a cooling process, from the stage unit 70. The unloading unit 60 may include a pick-up unit 61 configured to pick up the circuit board 10, and an arm configured to move along an x-axis, a y-axis, and a z-axis to position the pick-up unit 61 above the circuit board 10 to be picked up. The pick-up unit 61 may be rotatively located at an end portion of the arm, which is movable along the z-axis. For example, by moving the arm along each of the axes, the pick-up unit 61 may be positioned above the circuit board 10 to be unloaded, and by rotating the pick-up unit 61, the shapes of the circuit board 10 and the pick-up unit 61 may be matched such that the pick-up unit 61 may pick up the circuit board 10. The unloaded circuit board 10 may be placed on the conveyor 31 of a discharging unit of the transfer unit 30, and along the conveyor 31, the circuit board 10 may be discharged to an outside the chip bonding apparatus.

The cooling unit 90 may cool the stage unit 70, from which all the circuit boards 10 having completed a bonding process has been unloaded. The temperature of the stage 71 of the stage unit 70 from which the circuit board 10 has been unloaded after completing the bonding process and a natural cooling process, may be about 100° C., which is relatively high.

In a case where the circuit board 10 having the flip chips 20 thereon may be loaded again on the stage 71 without decreasing the temperature of the stage 71 below about 60° C., due to the high temperature of the stage 71, a deformation may occur at the circuit board 10. Thus, cooling units configured to separately lower the temperature of the individual stage 71 may be provided.

The cooling unit 90 may include a plurality of chambers containing cooling water. The shape of the chambers may have approximately the same shape as the shape of the stage 71, and the number of the chambers may be the same as the number of the stage 71. However, the structure of the cooling unit 90 is not limited hereto, and any shape or any structure that may cool the stage 71 may be included in the scope of the cooling unit 90. The temperature of the cooling water may be about 20° C.

By rotating the rotating unit 81, the stage unit 70, from which the circuit board 10 has been unloaded, may be moved to a position where the cooling unit 90 is located. The stage unit 70 moved to the position where the cooling unit 90 is located may be ascended toward the cooling unit 90 until making contact with the cooling unit 90. When the stage unit 70 contacts the cooling unit 90, the ascension of the stage unit 70 may be stopped.

The stage unit 70 contacting the cooling unit 90 may exchange heat with the cooling water in the cooling unit 90, thereby performing a cooling process. Once a temperature of the stage unit 70 reaches at or below a desired (or alternatively, predetermined) temperature, the temperature may be maintained.

The rotating unit 81 may include a rotating panel, on which the stage unit 70 is located, and a motor to rotate the rotating panel. The rotating panel 81 may be provided with a circular shape or a polygonal shape.

On the rotating panel 81, the plurality of stage units 70 may be located. The number of the stage units 70 being located on the rotating panel 81 is not limited in number, although example embodiments disclose that six stage units 70 are located on a rotating panel 81. Each of the stage units 70 may be located at any position, while the positions are divided as many as the number of the stage units 70.

Further, on the rotating panel 81, the transfer unit 30, the loading unit 40, the bonding unit 50, the unloading unit 60, and the cooling unit 90 may be located at desired (or alternatively, predetermined) positions.

The rotating unit 81, when a desired (or alternatively, predetermined) process time is expired, may rotate at the angle that is divided as many as the number of the stage units 70. For example, in a case when the total of six stage units 70 are located, the rotating unit 81 may rotate as much as 60°.

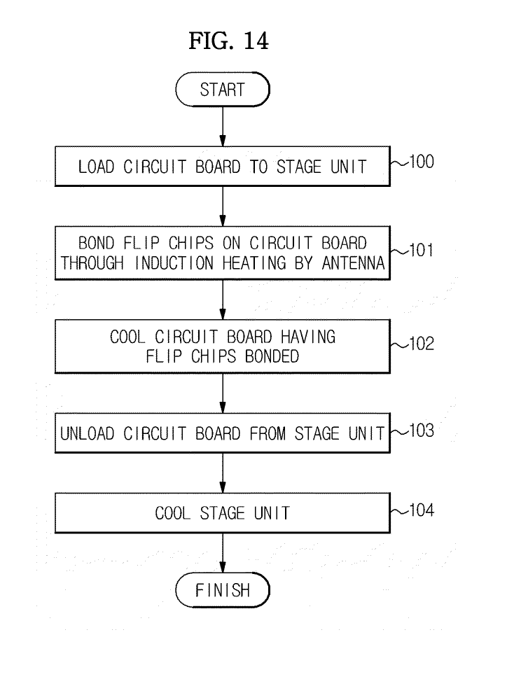

FIG. 14 is a flow chart showing a bonding method using a chip bonding apparatus according to example embodiments.

The circuit board 10 may be loaded on the stage unit 70 to bond the circuit board 10 having the flip chips 20 thereon (100).

First, using the conveyor 31 of the transfer unit 30, the circuit board 10 having the flip chips 20 thereon may be delivered to the loading unit 40. The transfer unit 30 may include the conveyor 31 configured to transfer the flip chips 20 and the circuit board 10, when the circuit board 10 having the flip chips 20 thereon is placed on the conveyor 31, and a motor configured to move the conveyor 31, for example, to left and right. The loading unit 40 may include the plurality of holders 41 aligned in a parallel manner, and configured to hold the circuit board 10 that is delivered from the transfer unit 30.

When the circuit board 10 having the flip chips 20 thereon is placed on the conveyor 31, the conveyor 31 may start to operate to deliver the circuit board 10 to one of the plurality of holders 41 of the loading unit 40. After delivering the circuit board 10 to the one holder 41 among the plurality of holders 41 aligned in a parallel manner, the transfer unit 30 may move the conveyor 31 to a position corresponding to a next holder 41. Accordingly, the circuit board 10 having the flip chips 20 thereon may be entirely delivered to the plurality of holders 41 provided at the loading unit 40.

When the delivery of the circuit board 10 to the holder 41 of the loading unit 40 is completed, the loading unit 40 holding the circuit board 10 may be placed in a standby mode until the stage unit 70, on which the circuit board 10 is to be loaded, is moved to a position corresponding to the loading unit 40.

When the stage unit 70, which is to be load with the circuit board 10, is moved to the position corresponding to the loading unit 40, the holder 41 of the loading unit 40 may place the circuit board 10, which is being held by the holder 41, onto the stage unit 70.

When the circuit board 10 is loaded onto the stage unit 70, the bonding unit 50, using induction heating, may attach, e.g., bond, the flip chips 20 to the circuit board 10 (101).

For a attaching, e.g., bonding, the flip chips 20 to the circuit board 10, the rotating unit 81, by rotating the stage unit 70 having loaded with the circuit board 10 by a desired (or alternatively, predetermined) angle, may move the stage unit 70 to a position corresponding to the bonding unit 50.

When the stage unit 70 is positioned at a lower portion of the bonding unit 50, the stage unit 70 may be ascended such that the circuit board 10 approaches the induction heating antenna 52 of the bonding unit 50. The stage unit 70 may move vertically using an ascension driving unit 82, which includes a transfer screw and a motor located at a lower portion of the rotating unit 81. The ascended stage unit 70, using the spacer 55 located at a lower surface of the induction heating antenna 52, may be provided with a certain interval from the induction heating antenna 52.

The spacer 55 may be located at both ends of the lower surface of the induction heating antenna 52. When the stage 71 loaded with the circuit board 10 approaches the induction heating antenna 52, the spacer 55 may enable the stage 71 to maintain a certain interval with respect to the induction heating antenna 52.

The spacer 55 may be supported by a holder 59 at a position spaced apart from the induction heating antenna 52 by a desired (or alternatively, predetermined) distance. Accordingly, when the stage 71 is ascended, as pushing the spacer 55 toward an upper direction to the maximum extent until the ascension of the spacer 55 is no longer possible, the induction heating antenna 52 and the stage 71 may be provided with an interval as wide as the thickness of the spacer 55.

The spacer 55 may be formed with a material, which does not flow an eddy current induced by the magnetic field formed at the surroundings of the induction heating antenna 52, and is resistant to a deformation at a high temperature. For example, the spacer 55 may be formed of a material that can endure a high temperature, e.g., ceramic or engineering plastic. The width of the end surface of the spacer 55, which determines the interval between the induction heating antenna 52 and the circuit board 10 (or, alternatively, the stage 71), may be designed based on considerations for an efficient and uniform bonding.

When the circuit board 10 loaded on the stage unit 70 and the induction heating antenna 52 are provided to maintain a certain interval by the spacer 55, the stage unit 70 may be additionally ascended to seal the bonding unit 50.

As the stage unit 70 is additionally ascended, the open lower surface of the bonding unit 50 and the base 78 of the stage unit 70 are closely adhered to each other. Thus, the bonding unit 50 may be sealed. When the additional ascending force, which is applied to the stage unit 70 to seal the bonding unit 50, is delivered to the first elastic unit 75, the first elastic unit 75 may be compressed. To the extent that the first elastic unit 75 is compressed, the stage unit 70 may be additionally ascended.

While the additional ascension of the stage unit 70 to seal the bonding unit 50 is performed by compressing the first elastic unit 75, the certain interval in between the induction heating antenna 52 and the stage 71 may not be affected, because the interval is maintained by the spacer 55 for a uniform bonding.

For example, the base 78 may be designed to have a same area as the area of an open lower surface of the bonding unit 50, and/or to have a same shape as the shape of the open lower surface of the bonding unit 50. Accordingly, when the stage unit 70 is ascended, the open lower surface of the bonding unit 50 may be closely adhered to the base 78 of the stage unit 70.

At a lower surface of the base 78 located at a lower surface of the stage 71, the second elastic unit 79 may be located. The second elastic unit 79 may be configured to perform the same role as the first elastic unit 75 located at the lower surface of the stage 71.

When the bonding unit 50 is sealed and an AC voltage is applied to the induction heating antenna 52, an eddy current may be induced and flow at the solder bumps 22 of the flip chips 20. Thus, the solder bumps 22 may be heated above a welding point temperature thereof. As the solder bumps 22 are heated and melted at the temperature above a welding point, the flip chips 20 and the board may be electrically connected, thereby attaching, e.g., bonding, the flip chips 20 to the circuit board 10. The adsorption hole 76 may be formed at the adsorption panel 72 of the stage 71 and, using a vacuum intake force at the adsorption hole 76, adsorptively attach, e.g., vacuum-chuck, the circuit board 10 at the adsorption panel 72. Thus, the deformation of the circuit board 10 while being heated in a bonding process may be prevented or minimized.

Further, the N₂ supplying hole 77 may be connected to the N₂ supply line 80 to supply nitrogen when a bonding is performed. Thus, when the bonding is being performed, the atmosphere may be turned into a nitrogen atmosphere. The solder bumps 22 of the flip chips 20, which are to contact the circuit board 10, may be processed with a chemical material referred to as flux. The flux is defined as a solvent processed on a surface of metal to prevent the surface of the metal, when the whole or a part of which is melted, from being oxidized by reacting to air. If the surface of the metal is melted during a bonding process, an oxidized substance layer may be formed. Thus, a quality bonding may be difficult to achieve. Thus, the flux may be processed to prevent an oxidization of the surface of metal. However, in a high temperature bonding process, the flux may be vaporized. Accordingly, the solder bumps 22 contacting the circuit board 10 may be oxidized, and thus a bonding process may not be performed properly. To resolve this problem, the atmosphere in which a bonding process is performed, may be composed of a nitrogen atmosphere.

When the bonding process is completed, the circuit board 10 may be cooled (102).

When the bonding process is completed at the bonding unit 50, the stage unit 70 may be descended, and is diverged from the bonding unit 50. When the stage unit 70 is diverged from the bonding unit 50, the rotating unit 81 may move the stage unit 70 by rotating at a desired (or alternatively, predetermined) angle for a cooling process.

The solder bumps 22 that are melted by the induction heating in the bonding process may be rapidly cooled when the induction heating is finished. However, because the circuit board 10 was also heated to a high temperature, if the circuit board 10 is immediately separated from the stage unit 70 upon completion of the bonding, the bonding quality may be substantially deteriorated. Thus, the circuit board 10 may be cooled below a certain temperature.

The circuit board 10 may be cooled by a natural cooling. Assuming that the total of six stage units 70 are located, the rotating unit 81 completing one process may move the stage unit 70 and proceed to a next process by rotating as much as 60°.

For example, when the bonding process is completed, the rotating unit 81 may be rotated as much as 60° to move the stage unit 70, and a first cooling process configured to cool the circuit board 10 for about 30 seconds to 40 seconds may be performed. The first cooling process may be a natural cooling.

When the first process is completed, same as the above, the rotating unit 81 may be rotated as much as 60° to move the stage unit 70, and a second cooling process configured to cool the circuit board 10 for about 30 seconds to 40 seconds may be performed. The second cooling process may be a natural cooling.

For the convenience of the description of the cooling process, the total of six units of the stage units 70 located is described as an example, but having more than the total of six units of the stage units 70 located and performing further beyond the second cooling process may be possible within the scope and spirit of the inventive concepts.

When the cooling process through, for example, the two stages is completed, the circuit board 10 may be unloaded from the stage unit 70 (103).

When the cooling process through, for example, the two stages is completed, the rotating unit 81 may be rotated as much as 60° to move the stage unit 70. When the stage unit 70 is moved, the unloading unit 60 may unload the circuit board 10, which has having completed with cooling, from the stage unit 70.

The unloading unit 60 may include a pick-up unit 61 configured to pick up the circuit board 10, and an arm configured to move along an x-axis, a y-axis, and a z-axis to position the pick-up unit 61 above the circuit board 10 to be picked up. The pick-up unit 61 is rotatively located at an end portion of the arm, which is movable along the z-axis. For example, by moving the arm along each of the axes, the pick-up unit 61 may be positioned above the circuit board 10 to be unloaded, and by rotating the pick-up unit 61, the shapes of the circuit board 10 and the pick-up unit 61 may be matched such that the pick-up unit 61 may pick up the circuit board 10. The unloaded circuit board 10 may be placed on the conveyor 31 of a discharging unit of the transfer unit 30, and along the conveyor 31, the circuit board 10 may be discharged to an outside of the chip bonding apparatus.

When the circuit board 10 is unloaded from the stage unit 70, the stage unit 70 may be cooled (104).

The temperature of the stage 71 of the stage unit 70 from which the circuit board 10 has been unloaded after completing the bonding process and the two-stage cooling process may be about 100° C., and the temperature as such is categorized as high temperature. In a case where the circuit board 10 having the flip chips 20 thereon may be loaded again on the stage 71 without decreasing the temperature of the stage 71 below about 60° C., due to the high temperature of the stage 71, a deformation may occur at the circuit board 10. Thus, the separate cooling units 90 may be provided to cool down the temperature of the individual stage 71.

The cooling unit 90 may include a plurality of chambers having cooling water. The shape of the chamber may have approximately the same shape as the shape of the stage 71, and the number of the chambers may be the same as the number of the stage 71. The temperature of the cooling water may be about 20° C.

By rotating the rotating unit 81, the stage unit 70, from which the circuit board 10 has been unloaded, may be moved to the position where the cooling unit 90 is located. The stage unit 70 moved to a position where the cooling unit 90 is located may be ascended toward the cooling unit 90 until making contact with the cooling unit 90. When the stage unit 70 contacts the cooling unit 90, the ascension of the stage unit 70 may be stopped. The stage unit 70 contacting the cooling unit 90, may exchange heat with the cooling water in the cooling unit 90, thereby performing a cooling process. Once a temperature of the stage unit 70 reaches at or below a desired (or alternatively, predetermined) temperature, about 60° C. for example, the temperature may be maintained.

When the cooling process of the stage unit 70 is completed, the rotating unit 81 may be rotated as much as 60° to move the stage unit 70, and another circuit board 10 having another set of flip chips 20 thereon may be loaded again to repeat each of the processes described above.

The chip bonding apparatus and/or the chip bonding method using the same according to the example embodiments described above, flip chips and a circuit board may be uniformly heated by using an AC magnetic field formed as AC current is applied to an induction heating antenna. Thus, an overheating of a circuit board and/or a defective chip bonding, which is caused by a non-uniform intensity of the inducted a magnetic field may be prevented or minimized.

In addition, by having a jig-jag type induction heating antenna that is larger than a large-area circuit board, a plurality of flip chips may be bonded at once, thereby substantially reducing the process time.

While example embodiments have been shown and described, it would be appreciated by one of ordinary skill in the art that changes may be made therein without departing from the spirit and scope of the inventive concepts defined by the following claims and their equivalents.

What is claimed is:

1. A chip bonding apparatus, comprising:
at least one stage unit configured to support a circuit board on which a chip is placed;
a rotating unit configured to rotatively transfer the at least one stage unit; and
a bonding unit including an induction heating antenna, the bonding unit configured to perform induction heating such that the chip is bonded to the circuit board.

2. The chip bonding apparatus of claim 1, wherein the chip includes a solder bump, a surface of the solder bump configured to be bonded to the circuit board, and
the induction heating antenna configured to perform the inductive heating on the solder bump, and wherein the at least one stage unit includes
a plurality of stages configured to support the circuit board, and
a base at a lower portion of the plurality of stages, the base configured to support the plurality of stages.

3. The chip bonding apparatus of claim 2, wherein each of the plurality of stages include an adsorption panel, the adsorption panel including adsorption holes defined therein, the adsorption holes configured to hold the circuit board using a vacuum.

4. The chip bonding apparatus of claim 3, wherein the adsorption panel further includes a nitrogen supplying/discharging hole defined therein, the nitrogen supplying/discharging hole configured to at least one of supply and discharge nitrogen, the adsorption panel formed of at least one of Invar, graphite, and silicon carbide.

5. The chip bonding apparatus of claim 2, wherein each of the plurality of stages further include a heat insulation panel, the heat insulation panel configured to retain.

6. The chip bonding apparatus of claim 2, wherein at least one of the plurality of stages and the base includes an elastic unit connected thereto.

7. The chip bonding apparatus of claim 1, wherein the at least one stage unit includes a plurality of stage units, the plurality of stage units located at a number of positions on the rotating unit and spaced apart from one another at intervals.

8. The chip bonding apparatus of claim 1, wherein the bonding unit includes
a chamber including an opening and configured to house the induction heating antenna therein, and wherein
the bonding unit configured to be closed by the at least one stage unit as the at least one stage unit moves toward the opening of the chamber.

9. The chip bonding apparatus of claim 1, wherein
a spacer is provided at a lower surface of the induction heating antenna, the spacer configured to maintain a distance between the at least one stage unit and the induction heating antenna, and
a contamination preventing panel is provided at a lower surface of the induction heating antenna, the contamination preventing panel configured to cover the circuit board on the at least one stage unit.

10. The chip bonding apparatus of claim 1, further comprising:
a loading unit configured to load the circuit board, on which the chip is placed, on the at least one stage unit;
an unloading unit configured to unload the circuit board having the chip bonded thereto from the at least one stage unit; and
a cooling unit configured to cool the at least stage unit from which the circuit board having bonded the chip thereon was unloaded.

11. The chip bonding apparatus of claim 10, wherein the cooling unit includes a chamber, the chamber configured to contain cooling water.

12. A chip bonding method, comprising:
loading a circuit board, on which a chip is placed, on a stage unit of a chip bonding apparatus;
inductively heating the chip to be bonded to the loaded circuit board;
first cooling the loaded circuit board after completing the bonding;
unloading the circuit board from the stage unit after the first cooling; and
second cooling the stage unit after unloading the circuit board.

13. The chip bonding method of claim 12, further comprising:
rotating the stage unit loaded with the circuit board to a first position corresponding to the bonding unit and
moving the stage unit to a second position at the bonding unit.

14. The chip bonding method of claim 12, further comprising:
moving the stage unit to be separated from the bonding unit after completing the bonding;
rotating the stage unit separated from the bonding unit; and
cooling the circuit board at a room temperature after rotating the stage unit.

15. The chip bonding method of claim 12, further comprising:
rotating the stage unit such that the stage unit is moved to a position corresponding to a cooling unit of the chip bonding apparatus after unloading the circuit board from the stage unit, and
moving the stage unit to contact the cooling unit such that the stage unit is cooled.

16. A chip bonding apparatus, comprising:
at least one stage unit configured to support a circuit board on which a chip is placed, the at least one stage unit configured to be movable; and
a bonding unit including an induction heating antenna, the bonding unit configured to bond the chip to the circuit board using a heat induced by the induction heating antenna, the bonding unit configured to be closed by the at least one stage unit while maintaining a distance between the induction heating antenna and the at least one stage unit.

17. The chip bonding apparatus of claim 16, wherein the bonding unit includes a high conductivity metallic structure surrounding the induction heating antenna, the high conductivity metallic structure configured to modulate an intensity of an AC magnetic field induced by the induction heating antenna.

18. The chip bonding apparatus of claim 16, wherein the at least one stage unit includes a nitrogen supplying/discharging unit, the nitrogen supplying/discharging unit configured at least one of to provide and to discharge nitrogen atmosphere.

19. The chip bonding apparatus of claim 16, wherein the bonding unit further includes at least one balance capacitor, the at least one balance capacitor configured to be connected to the induction heating antenna such that an arcing between the induction heating antenna and the circuit board is suppressed.

20. The chip bonding apparatus of claim 19, wherein the at least one balance capacitor includes a first balance capacitor connected to one side of the induction heating antenna, and a second balance capacitor connected between the other side of the induction heating antenna and a ground.
